(19) United States
(12) Patent Application Publication
(10) Pub. No.: US 2022/0082842 A1
(43) Pub. Date: Mar. 17, 2022

(54) MONOCULAR DISPLAY MODULE WITH LCOS MICRO DISPLAY

(71) Applicant: Visionaid Inc., Gumi-si (KR)

(72) Inventors: Manbok PARK, Seongnam-si (KR); Kyowung LEE, Suwon-si (KR); Sungil KIM, Pyeongtaek-si (KR); Joonseong SEO, Gumi-si (KR); Hwanyong YOO, Gumi-si (KR)

(73) Assignee: Visionaid Inc., Gumi-si (KR)

(21) Appl. No.: 17/110,198

(22) Filed: Dec. 2, 2020

(30) Foreign Application Priority Data
Sep. 16, 2020 (KR) 10-2020-0118783

(51) Int. Cl. G02B 27/01; A42B 3/04; G01R 33/00

(52) U.S. Cl. CPC G02B 27/0176; A42B 3/042; G02B 2027/0163; G02B 2027/0154; G01R 33/0023

(57) ABSTRACT

Disclosed is a monocular display module including a first coupling portion that is coupled to a safety helmet, a display unit that provides augmented reality or virtual reality to a left-eye or a right-eye of a user through an LCOS micro display, and a body portion that is coupled to the first coupling portion and the display unit, wherein respective center regions of the first coupling portion, the display unit, and the body portion are positioned in a straight line.

### CROSS-REFERENCE TO RELATED APPLICATIONS

A claim for priority under 35 U.S.C. § 119 is made to Korean Patent Application No. 10-2020-0118783 filed on Sep. 16, 2020, in the Korean Intellectual Property Office, the entire contents of which are hereby incorporated by reference.

### BACKGROUND

Embodiments of the inventive concept described herein relate to a monocular display module to which an LCOS micro display is applied.

Virtual reality (VR) is a technology that builds a virtual environment that feels like real, and augmented reality (AR) is a technology that projects virtual information onto an actual surrounding environment and expresses the virtual information and the actual surrounding environment together. The augmented reality (AR) and the virtual reality (VR) are developing from a concept of reality-virtuality continuum into mixed reality (MR) and augmented virtual (AV) forms that construct an environment by simultaneously fusing the reality with the virtual information.

In recent years, a display capable of providing such virtual reality or augmented reality to a user is widely used in industrial fields as well as external activities such as games, leisure, and the like.

As the display for providing such a virtual reality or augmented reality to the user, not only a liquid crystal display (LCD) but also a liquid crystal on silicone (LCOS) display is widely used.

The liquid crystal display (LCD) creates an image using a liquid crystal optically having anisotropy, which allows the liquid crystal display (LCD) to be manufactured thinner than a conventional cathode ray tube (CRT) and consume less power. Thus, the liquid crystal display (LCD) has been widely used. However, recently, the liquid crystal on silicone (LCOS) display having a fast response speed and an excellent viewing angle has been developed and is expanding an application field thereof.

### SUMMARY

Embodiments of the inventive concept provide a monocular display module capable of providing augmented reality or virtual reality to one of a left-eye and a right-eye of a user through an LCOS display in a state coupled to a safety helmet worn by the user.

The technical problems to be achieved in the inventive concept are not limited to the technical problems mentioned above, and other technical problems not mentioned may be clearly understood by those of ordinary skill in the art to which the inventive concept belongs from the following description.

According to an exemplary embodiment, a monocular display module includes a first coupling portion that is coupled to a safety helmet, a display unit that provides augmented reality or virtual reality to a left-eye or a right-eye of a user through an LCOS micro display, and a body portion that is coupled to the first coupling portion and the display unit, and respective center regions of the first coupling portion, the display unit, and the body portion are positioned in a straight line.

The first coupling portion may include an attachment/detachment unit, and the attachment/detachment unit may be attachable to and detachable from a brim of the safety helmet.

A rail may extend on the safety helmet, the rail may include a first rail extending along a front end of the brim of the safety helmet, the first coupling portion may include a rail coupling unit, and the rail coupling unit may move along the first rail.

The first rail may include a first fixing portion disposed in regions corresponding to regions in front of the left-eye and the right-eye of the user, and the first fixing portion may generate a first magnetic field and prevent a movement of the first coupling portion through attraction by the first magnetic field.

The rail may include a second rail extending from a middle region of the first rail to a rear surface region of the safety helmet past a topmost region of the safety helmet, and the first coupling portion may move along the first rail and the second rail.

The second rail may include a second fixing portion disposed in the topmost region and the rear surface region of the safety helmet, and the second fixing portion may generate a second magnetic field having a magnetic force different from a magnetic force of the first magnetic field and prevent the movement of the first coupling portion through attraction by the second magnetic field.

The rail coupling unit may include a magnetometer for sensing an intensity of the first magnetic field generated from the first fixing portion and sensing an intensity of the second magnetic field generated from the second fixing portion, the monocular display module may include a controller that controls an operation of the display unit, and the controller may control the display unit to operate when a magnetic force corresponding to the intensity of the first magnetic field is sensed through the magnetometer, and control the display unit to stop when a magnetic force corresponding to the intensity of the second magnetic field is sensed through the magnetometer.

The body portion may include a first distance adjusting portion capable of adjusting a length between the display unit and the body portion by extending in a first direction, a front direction of the user.

The body portion may include a second distance adjusting portion capable of adjusting a distance between the first coupling portion and the body portion by extending in a second direction perpendicular to the first direction.

The body portion may include an angle adjusting portion that adjusts an angle of the display unit with respect to the user, and the angle adjusting portion may include a gravity sensing unit for sensing a direction of gravity, and an angle adjusting unit for adjusting the angle of the display unit with respect to the user based on the direction of the gravity.

The body portion may include a second coupling portion, and the display unit may be attachable to or detachable from the body portion through the second coupling portion.

A rail may extend on the safety helmet, the rail may include a third rail extending along a headline at an inner bottom of the safety helmet, the first coupling portion may include a rail coupling unit, and the rail coupling unit may move along the third rail.

The first coupling portion may be coupled to a brim portion corresponding to a brim of the safety helmet when the brim is not formed on the safety helmet to be coupled to the first coupling portion, and the brim portion may be coupled to the safety helmet not provided with the brim.

The brim portion may be coupled to the safety helmet in a scheme of coupling by a magnetic force or in a fitting coupling scheme.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating a state in which a monocular display module according to a first embodiment of the inventive concept is coupled to a safety helmet;

FIG. 2 is a view illustrating a monocular display module according to a second embodiment of the inventive concept;

FIG. 3 is a view illustrating a state in which a monocular display module according to a second embodiment is coupled to a region of a brim of a safety helmet;

FIG. 4 is a view illustrating a state in which a monocular display module according to a second embodiment is coupled to a top region of a safety helmet;

FIG. 5 is a view illustrating a first distance adjusting portion and a second distance adjusting portion;

FIG. 6A is a view illustrating an angle adjusting portion;

FIG. 6B is a view illustrating a state in which a display unit 200 is coupled to a body portion 300 by a second coupling portion 400 and a display coupling groove 210;

FIG. 7 is a view illustrating a state in which a first coupling portion 100 moves along a third rail 33 formed inside the safety helmet 20; and

FIG. 8 is a view illustrating a monocular display module provided in a state in which a brim portion is coupled to a first coupling portion when a brim is not formed on a safety helmet.

### DETAILED DESCRIPTION

Other advantages and features of the inventive concept and methods of achieving the other advantages and features will become apparent with reference to embodiments as described below in detail with reference to the accompanying drawings. However, the inventive concept is not limited to the embodiments disclosed below, but may be embodied in various different forms. The present embodiment is provided to complete the disclosure of the inventive concept and to fully inform the scope of the invention to a person of ordinary skill in the art to which the inventive concept belongs. The inventive concept is only defined by the scope of the claims. Even not defined, all terms (including technical or scientific terms) used herein have the same meaning as commonly accepted by universal technology in the prior art to which this invention belongs. Terms defined by general dictionaries may be construed as having the same meaning as the related technology and/or the text of the present application, and won't be conceptualized or excessively formalized even when not clearly defined herein. The terminology used herein is for the purpose of describing embodiments only and is not intended to be limiting of the inventive concept. In the present specification, the singular forms ‘a’ and ‘an’ are intended to include the plural forms as well, unless the context clearly indicates otherwise. Terms ‘comprises’ and ‘includes’, and/or various conjugations of the terms used herein, for example, ‘comprising’, ‘including’, and the like do not preclude the presence or addition of one or more other compositions, constituents, components, steps, actions and/or elements. In the present specification, the term ‘and/or’ refers to each of the listed components or various combinations thereof. Terms ‘unit’, ‘device’, ‘block’, ‘module’, and the like used throughout the present specification may refer to a unit that processes at least one function or operation. For example, the ‘unit’, the ‘ device’, the ‘block’, the ‘module’, and the like may refer to hardware components such as a FPGA, or an ASIC. However, the ‘unit’, the ‘device’, the ‘block’, the ‘module’, and the like are not limited to software or hardware. The ‘unit’, the ‘device’, the ‘block’, and the ‘module’ may be configured to be in an addressable storage medium, or may be configured to execute one or more processors. Hereinafter, an embodiment of the inventive concept will be described in detail with reference to the drawings attached hereto.

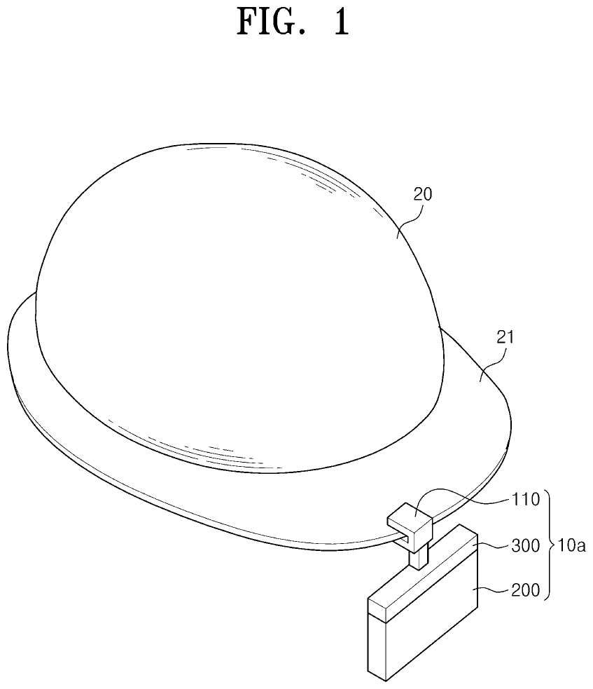

FIG. 1 is a view illustrating a state in which a monocular display module 10a according to a first embodiment of the inventive concept is coupled to a safety helmet 20.

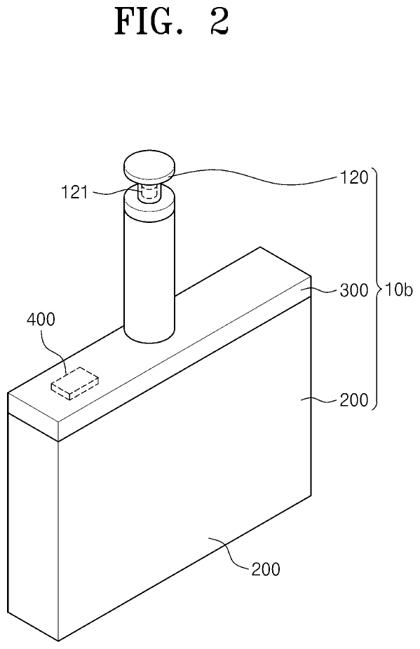

FIG. 2 is a view illustrating a monocular display module 10b according to a second embodiment of the inventive concept.

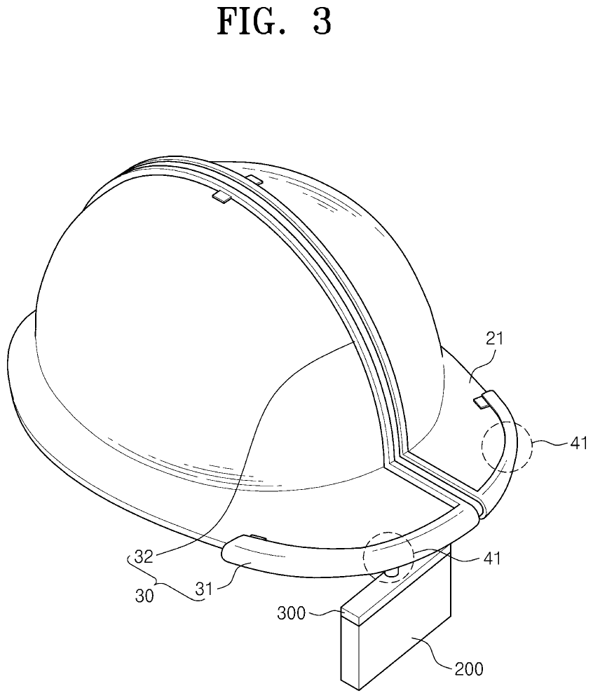

FIG. 3 is a view illustrating a state in which the monocular display module 10b in FIG. 2 is coupled to a region of a brim 21 of the safety helmet.

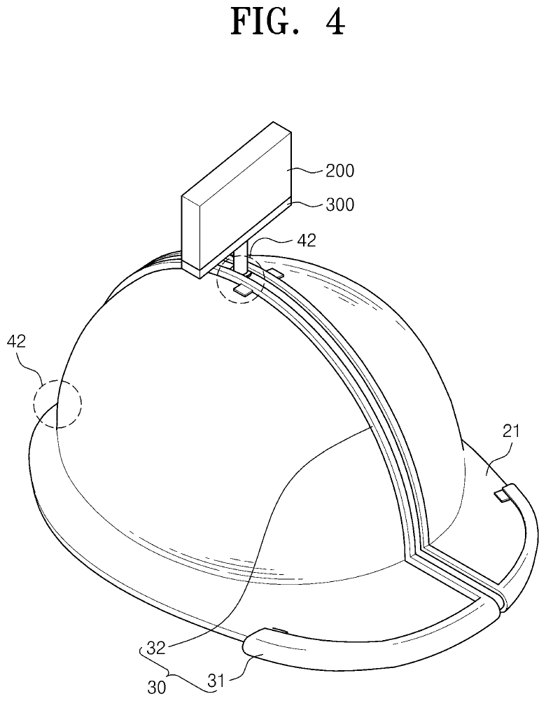

FIG. 4 is a view illustrating a state in which the monocular display module 10b in FIG. 2 is coupled to a top region of the safety helmet 20.

Referring to FIGS. 1 to 4, a monocular display module 10 may be formed as the monocular display module 10a according to the first embodiment or the monocular display module 10b according to the second embodiment.

The monocular display module 10 may provide augmented reality or virtual reality to one of a left-eye and a right-eye of a user through an LCOS display in a state coupled to the safety helmet 20 worn by the user.

The monocular display module 10 includes a first coupling portion 100, a display unit 200, and a body portion 300. The first coupling portion 100 is constructed such that the body portion 300 is coupled to the safety helmet. Such first coupling portion 100 may be formed as an attachment/detachment unit 110 shown in FIG. 1 or a rail coupling unit 120 shown in FIG. 2.

The display unit 200 is configured to provide the augmented reality or the virtual reality to the left-eye or the right-eye of the user through an LCOS micro display. Although not separately shown in the drawings, it will be apparent that a screen providing the augmented reality or the virtual reality is directed in a direction in which the display unit 200 faces the user.

The body portion 300 is constructed to be coupled to the first coupling portion 100 and the display unit 200. In this connection, center regions of the first coupling portion 100, the display unit 200, and the body portion 300 are positioned in a straight line.

The monocular display module 10 may include a power supply (not shown) that supplies power. The power supply may be included in the body portion 300, or may be disposed separately from the first coupling portion 100, the display unit 200, and the body portion 300. When the power supply is disposed separately, the power supply may be provided in a form disposed in some regions of the safety helmet. However, the power supply may be disposed to be separated from the safety helmet.

Referring to FIG. 1 again, the first coupling portion 100 of the monocular display module 10a according to the first embodiment of the inventive concept may include the attachment/detachment unit 110, and the monocular display module 10a may be coupled to the region of the brim 21 of the safety helmet by the attachment/detachment unit 110. In this connection, a coupling position of the attachment/detachment unit 110 may be preferable to be a position at which the user of the monocular display module 10a wearing the safety helmet 20 may easily see the display unit 200 of the monocular display module 10a through one of the left-eye and the right-eye thereof. However, when the user does not want to use the monocular display module 10a, even when being coupled to the safety helmet brim 21, the monocular display module 10a may be preferable to be coupled to an edge region of the safety helmet brim 21 that does not in a view of the user.

Referring to FIGS. 2 and 3 again, the monocular display module 10b according to the second embodiment of the inventive concept may include the rail coupling unit 120. The monocular display module 10b may be coupled to the region of the brim 21 of the safety helmet by the rail coupling unit 120.

More specifically, the rail coupling unit 120 may be coupled to a rail 30 formed on the safety helmet 20. The rail 30 may include a first rail 31 extends along a front end of the region of the brim 21 of the safety helmet. The rail coupling unit 120 may move in a direction of the left-eye or the right-eye of the user from the front end of the brim 21 of the safety helmet along the first rail 31. Thus, the user may more easily move a position of the monocular display module 10b to a desired position among the left-eye and the right-eye of the user as needed.

The first rail 31 may include a first fixing portion 41 disposed in regions corresponding to regions in front of the left-eye and the right-eye of the user. The first fixing portion 41 is formed as a component capable of generating a magnetic force and generates a first magnetic field corresponding to a preset magnetic field magnitude. The first fixing portion 41 prevents the movement of the rail coupling unit 120 through attraction by the first magnetic field, so that the rail coupling unit 120 may be fixed in a region corresponding to the region in front of one of the left-eye and the right-eye of the user. That is, the user may be more easily provided with the virtual reality or the augmented reality through the display unit 200 by fixing the rail coupling unit 120 at a desired position among the left-eye and the right-eye of the user.

Referring to FIG. 4 again, the rail 30 may include a second rail 32 extending from a middle region of the first rail 31 to a rear surface region of the safety helmet 20 past a topmost region of the safety helmet 20.

In this connection, the first coupling portion 100 is constructed to move along the first rail 31 and the second rail 32. More specifically, the rail coupling unit 120 included in the first coupling portion 100 is constructed to move along the first rail 31 and the second rail 32.

Thus, when the monocular display module 10b is not used, the user may move the monocular display module 10b to the top region of the safety helmet 20.

The second rail 32 may include a second fixing portion 42 disposed in the topmost region of the safety helmet 20 and the rear surface region of the safety helmet 20. Like the first fixing portion 41, the second fixing portion 42 is formed as a component capable of generating the magnetic force, and generates a second magnetic field corresponding to a preset magnetic field magnitude. The second fixing portion 42 prevents the movement of the first coupling portion 100 through attraction by the second magnetic field, so that the rail coupling unit 120 may be fixed in the topmost region of the safety helmet 20 or the rear surface region of the safety helmet 20. That is, when the monocular display module 10b is not used, the user may easily store the monocular display module 10b by fixing the rail coupling unit 120 in the topmost region of the safety helmet 20 or the rear surface region of the safety helmet 20.

The rail coupling unit 120 may include a magnetometer 121 for sensing an intensity of the first magnetic field generated from the first fixing portion 41 and sensing an intensity of the second magnetic field generated from the second fixing portion 42.

In this connection, the monocular display module 10b may further include a controller 400, and the controller 400 may be disposed inside the body portion 300. The controller 400 may be configured to receive the intensity of the magnetic field sensed by the magnetometer 121 through a wired network and control an operation of the display unit 200 based on the sensed intensity of the magnetic field However, in the case of the controller 400, unlike as shown in FIG. 2, the controller 400 may be disposed separately, not disposed inside the body portion 300. In this case, the controller 400 may be configured to receive the intensity of the magnetic field sensed by the magnetometer 121 through a wireless network and control the operation of the display unit 200 based on the received intensity of the magnetic field.

More specifically, when a magnetic force corresponding to the intensity of the first magnetic field is sensed through the magnetometer 121, the controller 400 may control the display unit 200 to operate. In addition, when a magnetic force corresponding to the intensity of the second magnetic field is sensed through the magnetometer 121, the controller 400 may control the display unit 200 to stop.

That is, without a need for the user to turn on/off the display unit 200 through a separate power switch, whether the user is using the monocular display module 10 may be automatically sensed through the intensity of the magnetic field sensed through the magnetometer 121 to turn on/off the display unit 200.

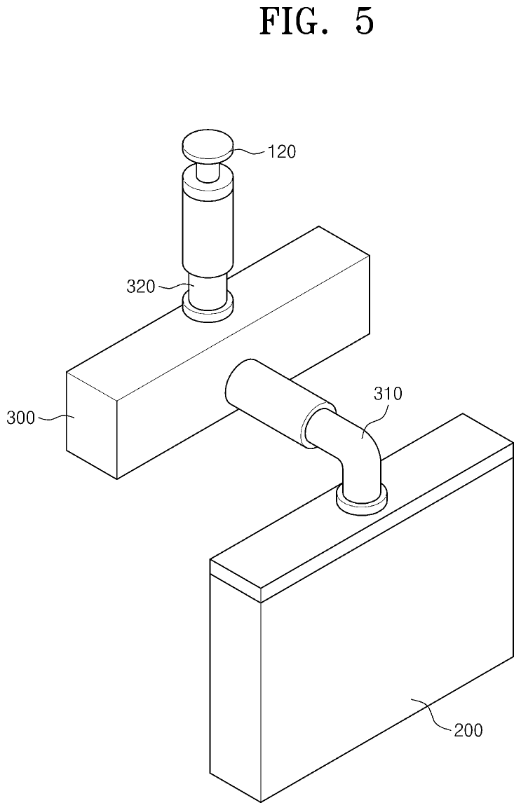

FIG. 5 is a view illustrating a first distance adjusting portion 310 and a second distance adjusting portion 320.

Referring to FIG. 5, the body portion 300 may include the first distance adjusting portion 310 and the second distance adjusting portion 320. The first distance adjusting portion 310 is constructed to be able to adjust a length between the display unit 200 and the body portion 300 by extending in a first direction that is a front direction of the user. The second distance adjusting portion 320 is constructed to be able to adjust a distance between the first coupling portion 100 and the body portion 300 by extending in a second direction perpendicular to the first direction. The user may appropriately adjust the position of the display unit 200 to a position at which the display unit 200 is easily used by the user through the distance adjustment by the first distance adjusting portion 310 and the second distance adjusting portion 320.

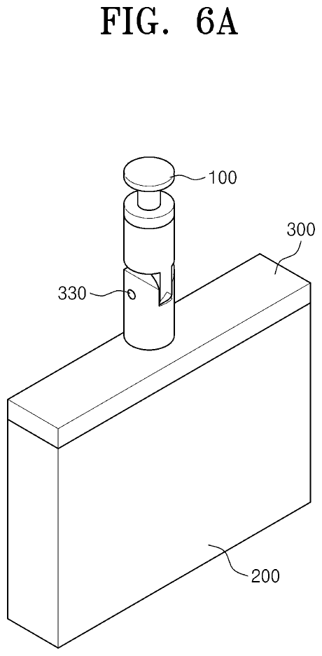

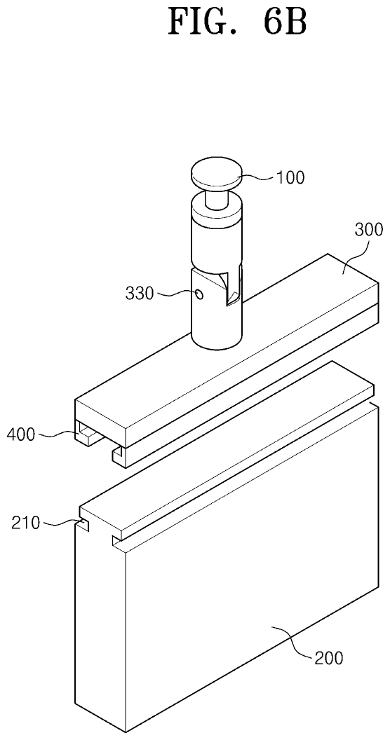

FIG. 6A is a view illustrating an angle adjusting portion 330.

Referring to FIG. 6A, the body portion 300 may include the angle adjusting portion 330. The angle adjusting portion 330 is constructed to adjust an angle of the display unit 200 with respect to the user. The angle adjusting portion 330 may include a gravity sensing unit (not shown) and an angle adjusting unit (not shown). The gravity sensing unit is configured to sense a direction of gravity. The angle adjusting unit is configured to adjust the angle of the display unit 200 with respect to the user based on the direction of the gravity sensed by the gravity sensing unit. Because the body portion 300 includes the angle adjusting portion 330, the display unit 200 may be always remained in a direction parallel to the gravity. Thus, the user may more easily see the display unit 200 even when the safety helmet 20 is inclined.

FIG. 6B is a view illustrating a state in which the display unit 200 is coupled to the body portion 300 by a second coupling portion 400 and a display coupling groove 210.

Referring to FIG. 6B, the body portion 300 may include the second coupling portion 400. The second coupling portion 400 is disposed on a bottom surface of the body portion 300, and constructed to fix the display unit 200 to the body portion 300. The display unit 200 is attachable to and detachable from the body portion 300. In this connection, the display coupling groove 210 may be defined in a top of the display unit 200. The display unit 200 may be attached to or detached from the body portion 300 in a scheme in which the second coupling portion 400 is inserted into the display coupling groove 210.

Although the rail coupling unit 120 is applied to the first coupling portion 100 in FIGS. 6A and 6B, it will be apparent that the attachment/detachment unit 110 rather than the rail coupling unit 120 may be applied.

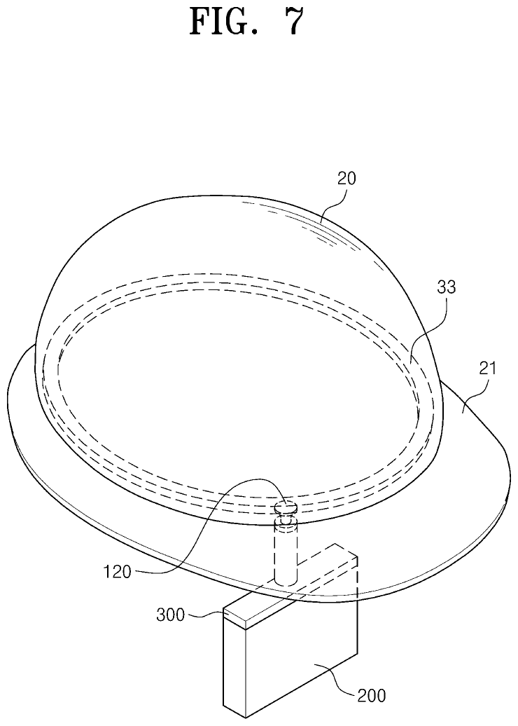

FIG. 7 is a view illustrating a state in which the rail coupling unit 120 moves along a third rail 33 formed inside the safety helmet 20.

Referring to FIG. 7, the rail 30 may include the third rail 33. The third rail 33 may be disposed on an inner bottom of the safety helmet 20. More specifically, the third rail 33 may extend along a headline of the user on the safety helmet 20. That is, the rail coupling unit 120 may be constructed to move along the third rail 33.

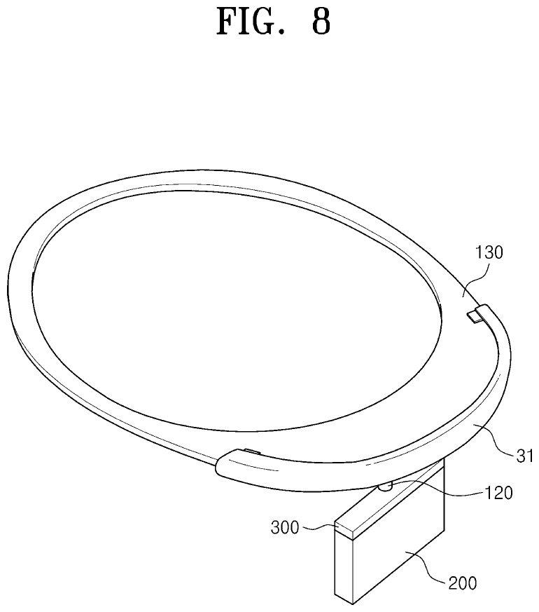

FIG. 8 is a view illustrating a monocular display module 10c according to a third embodiment provided in a state in which a brim portion 130 is coupled to the first coupling portion 100 when the brim is not formed on the safety helmet.

As shown in FIGS. 1, 3, and 4, the safety helmet 20 may be provided in a state in which the brim 21 of the safety helmet is already coupled thereto. However, some safety helmets may also be provided in a state in which the brim is not coupled thereto. The monocular display module 10c according to a third embodiment shown in FIG. 8 may be applied when the safety helmet is provided in the state in which the brim is not coupled thereto as described above.

More specifically, the monocular display module 10c according to the third embodiment may be provided in a state in which the first coupling portion 100 is coupled to the brim portion 130 corresponding to a shape of the brim of the safety helmet.

Referring to FIG. 8, the first coupling portion 100 may include the rail coupling unit 120, the rail coupling unit 120 may be coupled to the brim portion 130, and the brim portion 130 may be coupled to the safety helmet for which the brim is not provided.

Although FIG. 8 is shown on the assumption that the rail coupling unit 120 included in the first coupling portion 100 is coupled to the first rail 31 formed on the brim portion 130, in some cases, the attachment/detachment unit 110 included in the first coupling portion 100 may be directly coupled to the brim portion 130.

The brim portion 130 and the safety helmet for which the brim is not provided may be coupled to each other in a fitting coupling scheme. In addition, when a magnet is disposed in some regions of the brim portion 130 and the safety helmet for which the brim is not provided, the brim portion 130 and the safety helmet for which the brim is not provided may be coupled to each other by a magnetic force.

Although the inventive concept has been described through the embodiment above, the above embodiment is merely for describing the idea of the inventive concept and the inventive concept is not limited thereto. One of ordinary skill in the art will understand that various modifications may be made to the above-described embodiment. The scope of the inventive concept is determined only through interpretation of the appended claims.

The monocular display module according to the embodiment of the inventive concept may provide the augmented reality or the virtual reality to one of the left-eye and the right-eye of the user through the LCOS display while in the state coupled to the safety helmet worn by the user.

In one example, the effects that may be obtained from the inventive concept are not limited to the above-mentioned effects. Other effects not mentioned will be clearly understood by those of ordinary skill in the art to which the inventive concept belongs from the following description.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A monocular display module comprising:
a first coupling portion constructed to be coupled to a safety helmet;
a display unit configured to provide augmented reality or virtual reality to a left-eye or a right-eye of a user through an LCOS micro display; and
a body portion constructed to be coupled to the first coupling portion and the display unit,
wherein respective center regions of the first coupling portion, the display unit, and the body portion are positioned in a straight line.

2. The monocular display module of claim 1, wherein the first coupling portion includes an attachment/detachment unit,
wherein the attachment/detachment unit is constructed to be attachable to and detachable from a brim of the safety helmet.

3. The monocular display module of claim 1, wherein a rail extends on the safety helmet,
wherein the rail includes a first rail extends along a front end of a brim of the safety helmet,
wherein the first coupling portion includes a rail coupling unit,
wherein the rail coupling unit is constructed to move along the first rail.

4. The monocular display module of claim 3, wherein the first rail includes a first fixing portion disposed in regions corresponding to regions in front of the left-eye and the right-eye of the user,
wherein the first fixing portion is constructed to generate a first magnetic field and prevent a movement of the first coupling portion through attraction by the first magnetic field.

5. The monocular display module of claim 4, wherein the rail includes a second rail extending from a middle region of the first rail to a rear surface region of the safety helmet past a topmost region of the safety helmet,
wherein the first coupling portion is constructed to move along the first rail and the second rail.

6. The monocular display module of claim 5, wherein the second rail includes a second fixing portion disposed in the topmost region and the rear surface region of the safety helmet,
wherein the second fixing portion is constructed to generate a second magnetic field having a magnetic force different from a magnetic force of the first magnetic field and prevent the movement of the first coupling portion through attraction by the second magnetic field.

7. The monocular display module of claim 6, wherein the rail coupling unit includes a magnetometer for sensing an intensity of the first magnetic field generated from the first fixing portion and sensing an intensity of the second magnetic field generated from the second fixing portion,
wherein the monocular display module includes a controller configured to control an operation of the display unit,
wherein the controller is configured to:
control the display unit to operate when a magnetic force corresponding to the intensity of the first magnetic field is sensed through the magnetometer; and
control the display unit to stop when a magnetic force corresponding to the intensity of the second magnetic field is sensed through the magnetometer.

8. The monocular display module of claim 1, wherein the body portion includes a first distance adjusting portion constructed to be able to adjust a length between the display unit and the body portion by extending in a first direction, a front direction of the user.

9. The monocular display module of claim 8, wherein the body portion includes a second distance adjusting portion constructed to be able to adjust a distance between the first coupling portion and the body portion by extending in a second direction perpendicular to the first direction.

10. The monocular display module of claim 1, wherein the body portion includes an angle adjusting portion constructed to adjust an angle of the display unit with respect to the user,
wherein the angle adjusting portion includes:
a gravity sensing unit for sensing a direction of gravity; and
an angle adjusting unit for adjusting the angle of the display unit with respect to the user based on the direction of the gravity.

11. The monocular display module of claim 1, wherein the body portion includes a second coupling portion constructed such that the display unit is attachable to or detachable from the body portion.

12. The monocular display module of claim 1, wherein a rail extends on the safety helmet,
wherein the rail includes a third rail extending along a headline at an inner bottom of the safety helmet,
wherein the first coupling portion includes a rail coupling unit,
wherein the rail coupling unit is constructed to move along the third rail.

13. The monocular display module of claim 1, wherein the first coupling portion is coupled to a brim portion corresponding to a brim of the safety helmet when the brim is not formed on the safety helmet to be coupled to the first coupling portion,
wherein the brim portion is constructed to be coupled to the safety helmet not provided with the brim.

14. The monocular display module of claim 13, wherein the brim portion is constructed to be coupled to the safety helmet in a scheme of coupling by a magnetic force or in a fitting coupling scheme.
